(19) United States
(12) Patent Application Publication
(10) Pub. No.: US 2009/0134012 A1
(43) Pub. Date: May 28, 2009

(54) SPUTTERING APPARATUS AND SPUTTERING METHOD

(75) Inventors: Masahiro SHIBAMOTO, Yokohama-shi (JP); Kazuto YAMANAKA, Sagamihara-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/274,068

(22) Filed: Nov. 19, 2008

(30) Foreign Application Priority Data
Nov. 22, 2007 (JP) PCT/JP2007/072624
Jul. 29, 2008 (JP) 2008-194733

(51) Int. Cl. C23C 14/34

(52) U.S. Cl. 204/192.12; 204/298.07

(57) ABSTRACT

A gas introduction path intended for improving uniformity of the supply of a process gas is provided. A sputtering apparatus of the present invention has substrate holding means that holds a substrate and a gas introduction path, which has a plurality of gas spouts arranged in a closed curve in a plurality of positions surrounding the circumference of the substrate, and gas-introduction connections are provided in at least two positions substantially opposed to each other on the closed curve. Such two gas introduction paths are provided symmetrically with respect to the substrate on the front surface side and the rear surface side of the substrate.

### CROSS-REFERENCES TO RELATED APPLICATIONS

This application claims the benefit of priority from International Application No. PCT/JP2007/072624, filed on Nov. 22, 2007 and Japanese Patent Application No. 2008-194733 filed Jul. 29, 2008, the entire contents of which are incorporated herein by reference.

### BACKGROUND OF THE INVENTION

1. Field of the Invention

The present invention relates to a sputtering apparatus and, more particularly, to a sputtering apparatus and a sputtering method for performing film formation onto a substrate based on reactive sputtering by using a reactive gas.

2. Related Background Art

In a sputtering apparatus, the material for a target attached to a cathode is sputtered out by ions and target material particles (sputtered particles) generated thereby are caused to strike against a substrate disposed so as to be opposed to the target, whereby a thin film of the target material is formed. For this reason, in the sputtering apparatus, a gas for causing sputtering to be performed (a sputtering gas or a plasma generating gas) is introduced into a vacuum chamber by use of a vacuum container and energy is given by supplying high-frequency power to the target or applying DC voltage to the target, whereby a plasma is generated and ions for making sputtered particles are generated. The target material is deposited on the surface of the substrate on the basis of the sputtered particles striking against the surface of the substrate.

A reactive sputtering apparatus is known as the above-described sputtering apparatus. In a reactive sputtering apparatus (hereinafter simply referred to as a “sputtering apparatus”), a reactive gas such as oxygen and nitrogen is introduced into the vacuum chamber in addition to an inert gas (a sputtering gas), such as argon (Ar), for causing sputtering to be performed. In such a sputtering apparatus, target material particles are sputtered out by the collision of argon ions in the generated plasma against the target material, and the target material particles react with the above-described reactive gas, with the result that a film due to a reactive substance is deposited on the surface of the substrate. When the concentration of the reactive gas is high, compound layers are formed by the reactive gas on the surface of the target material and a reactive substance of a desired composition is deposited on the substrate by the sputtering of the compound layers.

Japanese Patent Application Laid-Open No. H5-243155 discloses a sputtering apparatus that uniformly supplies a reactive gas simultaneously from a semiconductor substrate and from the periphery of a sputtering source. Japanese Patent Application Laid-Open No. 2004-346406 discloses a sputtering apparatus provided with an introduction mechanism that causes a reactive gas to flow from the middle part of a cathode unit outward along the surface of a target. Japanese Patent Application Laid-Open No. 2001-107228 discloses a reactive sputtering apparatus capable of obtaining a good film thickness by making the supply of a process gas uniform in forming a film on a large substrate.
[Patent Reference 1] JP Laid-Open Gazette H05-243155
[Patent Reference 2] JP Laid-Open Gazette 2004-346406
[Patent Reference 3] JP Laid-Open Gazette 2001-107228

However, it is impossible to sufficiently obtain the uniformity of the supply of a process gas even with the above-described conventional techniques.

### SUMMARY OF THE INVENTION

To solve the above-described problem, a sputtering apparatus of the present invention has substrate holding means that holds a substrate and a gas introduction path, which has a plurality of gas spouts arranged in a closed curve in a plurality of positions surrounding the circumference of the substrate, and gas-introduction connections are provided in at least two positions substantially opposed to each other on the closed curve. In this specification, a process gas means an inert gas or a reactive gas.

According to the present invention, a process gas can be uniformly introduced in the substrate. For this reason, the uniformity of film characteristics can be improved.

### BRIEF DESCRIPTION OF THE DRAWINGS

FIG. 1A is a sectional view of a gas introduction mechanism according to an embodiment of the present invention as viewed from the front surface side of a substrate.

FIG. 1B is a sectional view of a gas introduction mechanism according to an embodiment of the present invention as viewed from the rear surface side of a substrate.

FIG. 1C is another sectional view of a gas introduction mechanism according to an embodiment of the present invention.

FIG. 1D is a further sectional view of a gas introduction mechanism according to an embodiment of the present invention.

FIG. 2 is a sectional view of a vacuum chamber according to an embodiment of the present invention.

FIG. 3 is a still further sectional view of a gas introduction mechanism according to an embodiment of the present invention.

FIG. 4 is a plan view showing a schematic construction of a thin-film forming apparatus according to an embodiment of the present invention.

FIG. 5 is a schematic front view of a substrate holder and moving means in the thin-film forming apparatus shown in FIG. 4.

FIG. 6 is a schematic side sectional view of the substrate holder and moving means in the thin-film forming apparatus shown in FIG. 4.

FIG. 7 is a schematic side sectional view to illustrate the construction of the thin-film forming apparatus shown in FIG. 4.

### DESCRIPTION OF THE PREFERRED EMBODIMENTS

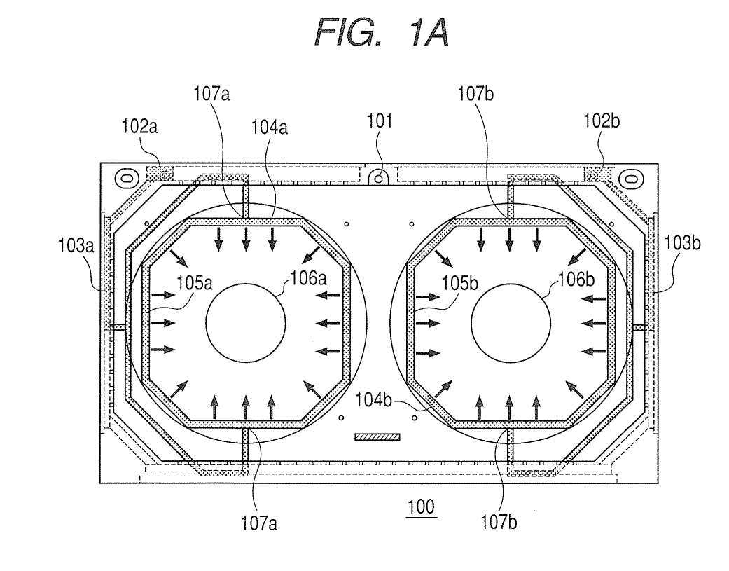

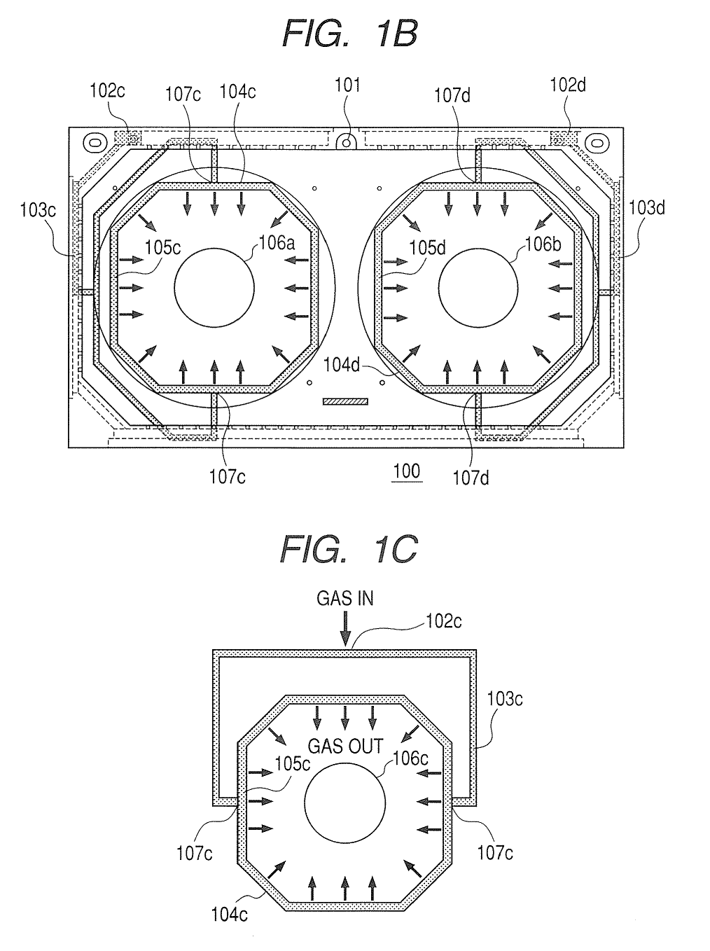

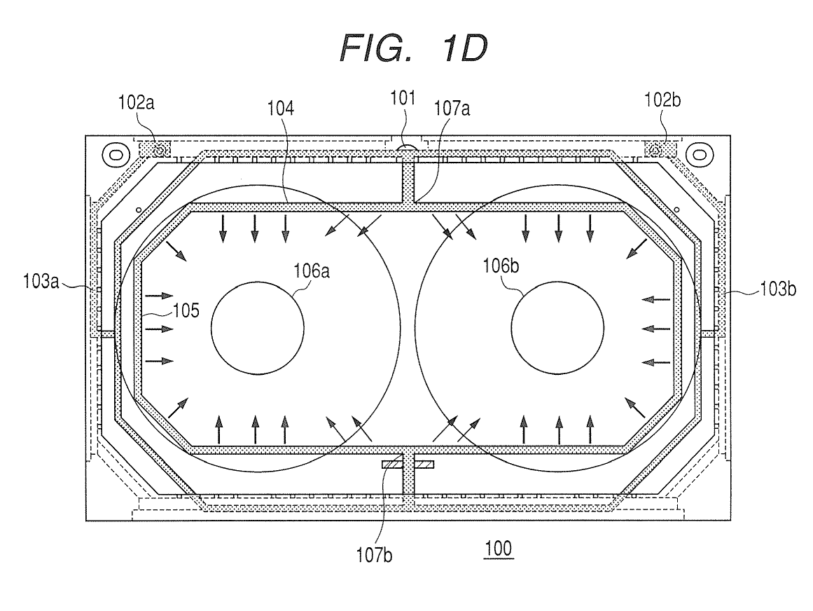

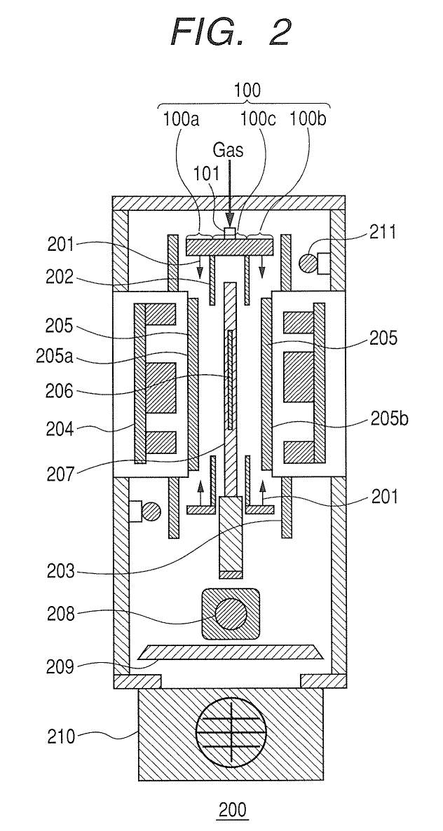

FIG. 1A is a side sectional view of a gas introduction mechanism 100 as viewed from a direction perpendicular to the surfaces of substrates arrayed longitudinally. As shown in FIG. 1A, in the interior of the gas introduction mechanism 100, a substrate 106a and a substrate 106b supported by a substrate holder (shown in FIG. 2) are supported in a longitudinally placed condition (a vertical posture) and arranged symmetrically with respect to the central axis of the gas introduction mechanism 100. The substrates 106a, 106b are in the shape of a thin disk as a whole. In the middle upper part of the gas introduction mechanism 100, a gas inlet 101 for introducing gas from the outside (a single gas supply source) is provided, and a process gas (an inert gas and a reactive gas) is introduced from this gas inlet 101.

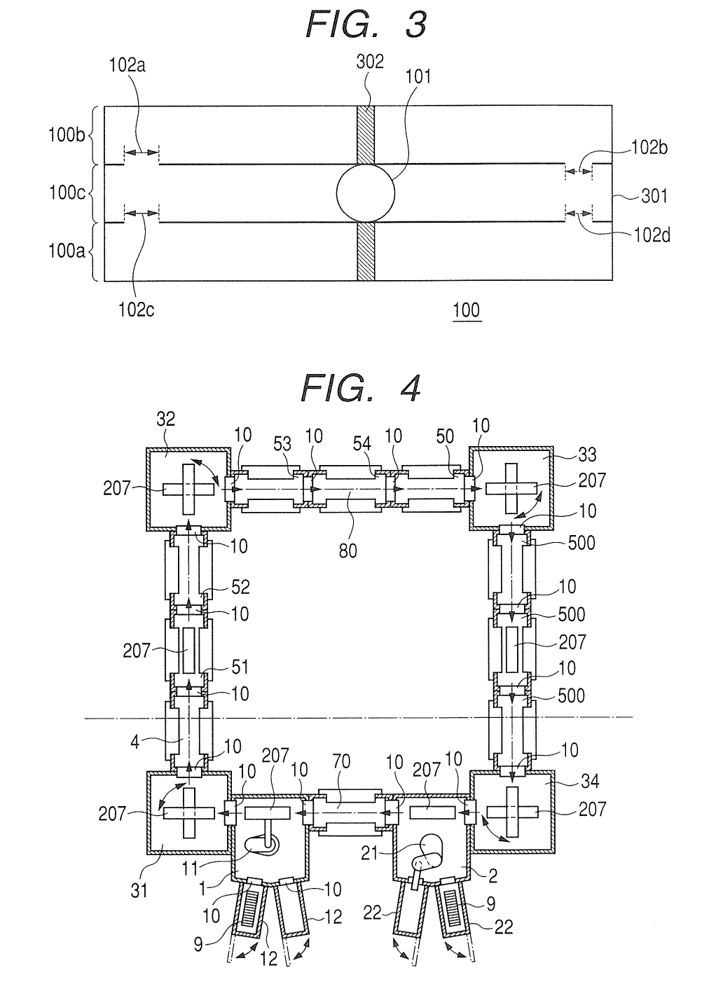

An introduced process gas flows in the interior of the gas introduction mechanism 100 as shown in FIG. 3, which will be described later, and reaches gas inflow ports 102a and 102b. The process gas that flows in out of the gas inflow port 102a provided in the left upper part of the gas introduction mechanism 100 flows from the gas inflow port 102a to a gas pipe 103a, then reaches a gas introduction path 104a that is arranged so as to surround the whole circumference of the substrate 106a, and is spouted from a plurality of gas spouts 105a installed in the gas introduction path 104a. The gas spouts 105a are arranged in a plurality of positions surrounding the circumference of the substrate 106a. The gas introduction path 104a is of a hollow construction. In this embodiment, the gas pipe 103a is branched, and the branched gas pipe 103a and the gas introduction path 104a are connected to each other in two gas-introduction connections 107a that are substantially opposed to each other. Incidentally, it is preferred that the two gas-introduction connections 107a be provided substantially symmetrically with respect to the central axis of the gas introduction path 104a. This enables a process gas to be uniformly supplied to the substrate 106a.

It is preferred that the gas spouts 105a be provided on the circumference side of the gas introduction path 104a symmetrically with respect to the central axis of the gas introduction path 104a. In this embodiment, the gas introduction path 104a is arranged so as to surround the circumference of the substrate 106a and is arranged substantially symmetrically with respect to the center line of the substrate 106a. On the other hand, the process gas that flows in out of the gas inflow port 102b provided in the right upper part of the gas introduction mechanism 100 flows from the gas inflow port 102b to a gas pipe 103b, then reaches a gas introduction path 104b that is arranged so as to surround the whole circumference of the substrate 106b, and is spouted from a plurality of gas spouts 105b installed in the gas introduction path 104b. The gas spouts 105b are arranged in a closed curve in a plurality of positions surrounding the circumference of the substrate 106b. In this embodiment, the gas pipe 103b is branched, and the branched gas pipe 103b and the gas introduction path 104b are connected to each other in two gas-introduction connections 107b that are substantially opposed to each other.

Incidentally, it is preferred that the two gas-introduction connections 107b be provided substantially symmetrically with respect to the central axis of the gas introduction path 104b. It is preferred that the plurality of gas spouts 105b be provided on the circumference side of the substrate of the gas introduction path 104b and symmetrically with respect to the central axis of the gas introduction path 104b. In this embodiment, the gas introduction path 104b is arranged so as to surround the circumference of the substrate 106b and is arranged substantially symmetrically with respect to the center line of the substrate 106b. The gas introduction path 104b is of a hollow construction. This construction enables the ease with which the gas supplied to the substrate flows to be made uniform. For example, as described on page 38 of “Shinkuu Gijutsu Jitsumu Tokuhon (Vacuum Technique Practice Reader),” written by Katsuya Nakayama, Ohmsha, Ltd., the conductance of a gas pipe is proportional to the section area A of the gas pipe and is inversely proportional to the length 1 of the gas pipe. The construction as shown in FIG. 1A enables a process gas spouted from the gas spout 105 to be introduced virtually uniformly on the surface of the substrate 106.
[Non-Patent Reference 1] Shinkuu Gijutsu Jitsumu Tokuhon (Vacuum Technique Practice Reader) written by Katsuya Nakayama, Ohmsha, Ltd.

It is possible to set the opening diameter of the gas spouts 105a, 105b provided in places where the distance from the reactive gas inflow ports 102a, 102b is short at a value smaller than the opening diameter of the gas spouts 105a, 105b provided in places where the distance from the reactive gas inflow ports 102a, 102b is long. Furthermore, in order to make the spouted gas uniform, the number of the gas spouts 105a, 105b provided in places where the distance from the reactive gas inflow ports 102a, 102b is short may be set at a value smaller than the number of the gas spouts 105a, 105b provided in places where the distance from the reactive gas inflow ports 102a, 102b is long. Furthermore, because conductance differs depending on the kind of the gas to be used, the number and the size of the opening diameter of gas spouts may also be set beforehand according to the kind of the gas. The number, size and direction of gas spouts can be adjusted.

FIG. 1B is a sectional view of the gas introduction mechanism 100 as viewed from the rear side position reverse to the position of FIG. 1A. As shown in FIG. 1B, other gas introduction paths 102c-103c-07c-04c-05c; 102d-103d-107d-104d-105d, which have substantially the same shape, are formed so as to interpose the gas introduction paths and substrates 106a, 106b shown in FIG. 1A. That is, the gas introduction paths shown in FIG. 1A and the gas introduction paths shown in FIG. 1B are provided substantially symmetrically with respect to the same plane as the substrate. More specifically, the gas inflow port 102a and the gas inflow port 102c, the gas pipe 103a and the gas pipe 103c, the gas introduction path 104a and the gas introduction path 104c, the gas spout 105a and the gas spout 105c, and the gas-introduction connection 107a and the gas-introduction connection 107c are provided substantially symmetrically with respect to the same plane as the substrate. Furthermore, the gas inflow port 102b and the gas inflow port 102d, the gas pipe 103b and the gas pipe 103d, the gas introduction path 104b and the gas introduction path 104d, the gas spout 105b and the gas spout 105d, and the gas-introduction connection 107b and the gas-introduction connection 107c are provided substantially symmetrically with respect to the same plane as the substrate.

FIG. 1C is a diagram showing another embodiment according to the arrangement of the gas inflow port 102, the gas pipe 103, the gas introduction path 104, the gas spouts 105, the gas-introduction connection 107 and the substrate 106. In this embodiment, a gas introduction path 104c is arranged so as to surround the circumference of a substrate 106c and is arranged substantially symmetrically with respect to the center line of the substrate 106c. In this embodiment, the gas that flows in out of a gas inflow port 102c is branched into two, reaches the gas introduction path 104c via a gas pipe 103c, and is spouted from gas spouts 105c provided on the gas introduction path 104c and arranged in a plurality of places surrounding the circumference of the substrate 106c. The gas pipe 103c and the gas introduction path 104c are connected to each other in two gas-introduction connections 107c that are substantially opposed to each other. Incidentally, it is preferred that the two gas-introduction connections 107c be provided symmetrically with respect to the center axis of the gas introduction path 104c. For the arrangement of the gas pipe 103c and the gas introduction path 104c with respect to the substrate 106, a design change may be made appropriately on the basis of the gist of the present invention. For example, the gas introduction path can be formed in the shape of a regular polygon or a circle. Incidentally, though a detailed description is omitted, in the same manner as shown in FIGS. 1A and 1B, a gas introduction mechanism shown in FIG. 1C and the other gas introduction mechanism are arranged on the front surface side and the rear surface side of the substrate respectively, each substantially symmetrically with respect to the substrate surfaces so that films can be formed on both surfaces of each substrate.

FIG. 1D is a diagram showing a further embodiment according to the arrangement of the gas inflow port 102, the gas pipe 103, the gas introduction path 104, the gas spouts 105, the gas-introduction connection 107 and the substrate 106. Although in the gas introduction mechanism 100 of FIG. 1A, gas introduction paths are provided so as to surround the whole circumference of each of the two substrates, in this embodiment a gas introduction path is provided so as to surround the whole circumference of the two substrates. In this embodiment, the gas introduction path is formed so that a process gas flows in out of two gas inflow ports 102a and 102b.

First, the gas that flows in out of the gas inflow port 102a reaches the gas introduction path 104 via a gas pipe 103a. The gas pipe 103a and the gas introduction path 104 are connected to each other in two gas-introduction connections 107a and 107b that are substantially opposed to each other. It is preferred that the gas-introduction connections 107a and 107b be provided substantially symmetrically with respect to the central axis of the gas introduction path 104. The gas that reaches the gas introduction path 104 is spouted from a plurality of gas spouts 105 provided on the gas introduction path 104 and arranged in a plurality of positions surrounding the circumferences of two substrates 106a, 106b. On the other hand, the gas that flows in out of the gas inflow port 102b reaches the gas introduction path 104 via a gas pipe 103b. The gas pipe 103b and the gas introduction path 104 are connected to each other in the two gas-introduction connections 107a and 107b that are substantially opposed to each other. The gas that reaches the gas introduction path 104 is spouted from the plurality of gas spouts 105 provided on the gas introduction path 104 and arranged in a plurality of positions surrounding the circumferences of two substrates 106a, 106b. Also in this embodiment, the gas introduction path 104 is arranged substantially symmetrically with respect to the center line of the substrates 106a, 106b. This construction enables the gas to be uniformly supplied to the substrates. Incidentally, though a detailed description is omitted, in the same manner as shown in FIGS. 1A and 1B, a gas introduction mechanism different from the gas introduction mechanism shown in FIG. 1D is arranged each on the front surface side and the rear surface side of the substrate, each substantially symmetrically with respect to the substrate surfaces so that films can be formed on both surfaces of each substrate.

FIG. 2 is a sectional view of the interior of a vacuum chamber 200 as viewed from the side direction, and shows the positional relationship of the gas introduction mechanism 100 provided within the chamber 200. First, the vacuum chamber 200 will be described. The vacuum chamber 200 is provided with a turbo-molecular pump 210 and a main valve 209, and these components constitute a gas exhaust system of the vacuum chamber 200. A conveyance magnet 208 is arranged above the main valve 209, and a substrate holder 207 that holds a substrate 206 is arranged further above the conveyance magnet 208 so that the substrate holder 207 is capable of conveyance along the conveyance magnet 208 by using the magnetic force of the conveyance magnet 208.

As shown in FIG. 2, the gas introduction mechanism 100 is constructed so as to have a space formed by a set of center shields 202 in the middle part of the width direction of the gas introduction mechanism 100, and the substrate holder 207 arranged above the conveyance magnet 208 is disposed in this space. The substrate holder 207 can hold a plurality of substrates present on the same plane. Target placement beds 205a, 205b are arranged, with the substrate holder 207 interposed therebetween, and a target 205 is placed on each of the target placement beds 205a, 205b. A magnet 204 is placed behind the target 205. The gas introduction mechanism 100 has a left-hand part 100a of the gas introduction mechanism 100 and a right-hand part 100b of the gas introduction mechanism 100 so that a gas supplied from the gas inlet 101 can be introduced into the gas introduction mechanism 100 as a gas 201. The arrows of FIG. 2 indicate the flow of the gas 201. The left-hand part 100a of the gas introduction mechanism 100 and the right-hand part 100b of the gas introduction mechanism 100 each have a gas introduction path. These gas introduction paths are of a hollow construction and constitute a pair of gas introduction paths provided symmetrically, with the substrate holder 207 interposed therebetween. The target 205 and the substrate held by the substrate holder 207 are in communication with each other via the hollow construction of the gas introduction paths. A middle part 100c having the gas inlet 101 is provided between the left-hand part 100a and the right-hand part 100b of the gas introduction mechanism 100. These gas introduction paths in two rows enable a gas to be introduced from opposite surfaces of a plurality of substrates 206 held by the substrate holder 207. As described above, the gas introduction mechanism of the present invention has two gas introduction paths that are opposed to each other, with at least one substrate 206 interposed therebetween, held by the substrate holder 207.

As described above, the gas introduction mechanism 100 has the center shields 202, and the center shields 202 are arranged, with part of the substrate holder 207 interposed therebetween. However, it is preferred that the center shields 202 be arranged so as not to overlap a project plane in the normal line direction of the substrate 206 held by the substrate holder 207. And outer shields 203 facing the center shields 202 extend from the vicinity of opposing ends of the targets 205 each having a magnet 204 behind. This construction enables the gas 201 to be uniformly supplied to the substrate 206 while preventing the diffusion of the gas 201. A bake heater 211 is intended for evaporating impurities (water etc.) adhering to the interior of the vacuum chamber 200, the shields and the like in the chamber by heating impurities.

The operation of the vacuum chamber 200 shown in FIG. 2 will be described below. First, before the conveyance of the substrate holder 207 into the vacuum chamber 200, it is necessary to put the vacuum chamber 200 into a mode which is that an inert gas Ar supplied from an unillustrated gas supply source via the gas introduction mechanism 100 constantly flows within the vacuum chamber 200. For this purpose, the main valve 209 is brought into a half open condition of intermediate stop in order to control the pressure. As a result of this, the Ar gas supplied by the gas introduction mechanism 100 passes in the vicinity of the target 205, flows into the turbo-molecular pump or cryogenic pump 210 and is exhausted. Next, a gate valve of the vacuum chamber 200 is opened and the substrate holder 207 in another chamber is conveyed into the vacuum chamber 200. Next, an active gas (oxygen or nitrogen) supplied from an unillustrated gas supply source via the gas introduction mechanism 100 is supplied to the vicinity of the target 205. Also at this time, Ar is constantly flowing. After a lapse of a prescribed time, when the pressure has become uniform, a plasma discharge is caused to be performed by use of an unillustrated power source. Ions in the plasma are attracted by a cathode (not shown) arranged on the side opposite to a sputtered surface of the target 205, and sputter the target 205 and target material particles are sputtered out. Sputtered target material particles react with the active gas, with the result that a film due to a reactive substance is deposited on the surface of the substrate 206. After the finish of the discharge, the supply of the active gas is stopped, the gate valve opens, and the substrate holder 207 is conveyed. It is also possible not to cause the inert gas Ar and the active gas to flow constantly, and the inert gas may be controlled in the same manner as with the active gas.

FIG. 3 is a sectional view of the gas introduction mechanism 100 of the present invention as viewed from just above. In the upper part of the gas introduction mechanism 100, the gas inlet 101 for introducing a process gas from a single gas supply source is provided. A process gas introduced from the gas inlet 101 flows uniformly along the middle part 100c (gas pipe) of the gas introduction mechanism 100 from the gas inlet 101 toward both end parts 301 of the gas introduction mechanism 100, and branches in the gas inflow ports 102a, 102b, 102c and 102d provided in the vicinity of the end parts 301. The process gas that follows into the gas inflow ports 102a, 102b is introduced into the left-hand part 100a of the gas introduction mechanism 100 arranged so as to surround the substrate 106 as shown in FIG. 1. On the other hand, the process gas that flows into the gas inflow ports 102c and 102d flows along the right-hand part 100b of the gas introduction mechanism 100 shown in FIG. 2 of the gas introduction mechanism 100. The gas introduction mechanism 100 further has an inner wall 302. FIG. 3 shows the condition of the interior of the left-hand part 100a, right-hand part 100b and middle part 100c of the gas introduction mechanism 100 as viewed from the top surface side, and the condition of the left-hand part 100a and right-hand part 100b of the gas introduction mechanism 100 as viewed from the side corresponds to the gas pipes 103a, 103b, 103c, 103d, and the gas introduction paths 104a, 104b, 104c, 104d shown in FIG. 1 and FIG. 2.

Incidentally, as described above, the gas is introduced into the gas introduction mechanism 100 by use of the single gas inlet 101 from the single supply source and hence the control of the gas in the whole gas introduction mechanism 100 is easy and this is advantageous also in terms of the manufacturing cost. However, this is not always restrictive, but for example, a gas inlet may be provided individually for the left-hand part 100a and the right-hand part 100b of the gas introduction mechanism 100 and furthermore, a gas supply source may be provided individually for the gas inlet of the left-hand part 100a and the gas inlet of the right-hand part 100b.

FIG. 4 is a plan view showing a schematic construction of a thin-film forming apparatus 400 according to the first embodiment of the present invention. In the apparatus of this embodiment, a plurality of vacuum chambers 1, 2, 4, 31 to 34, 50 to 54 and 500 are arranged in series along a square contour. Each of the vacuum chambers is a vacuum vessel that is exhausted by a dedicated exhaust system or an exhaust system that serves a plurality of vacuum chambers. A gate valve 10 is arranged at the boundary of the respective vacuum chambers. A substrate 9 is conveyed by being held by a substrate holder 207. A square-shaped moving path 80 is provided along the plurality of vacuum chambers that are arranged in series, and moving means that moves the substrate holder 207 along this moving path 80 is provided. The substrate holder 207 is conveyed within each chamber by this moving means while holding the substrate 9.

Out of the plurality of vacuum chambers, two vacuum chambers arranged on one side of the square provide a load lock chamber 1 that performs the loading of the substrate 9 on the substrate holder 207 and an unload lock chamber 2 that performs the recovery of the substrate 9 from the substrate holder 207. Incidentally, in the square-shaped moving path 80, the portion between the load lock chamber 1 and the unload lock chamber 2 provides a return moving path for returning the substrate holder 207 from the unload lock chamber 2 to the load lock chamber 1. Within the load lock chamber 1, a loading robot 11 that loads the substrate 9 on the substrate holder 207 is provided. The loading robot 11 holds, by use of an arm thereof, the substrate 9 in quantities of two simultaneously from a substrate charging stocker and loads the substrates 9 on the substrate holder 207. Within the unload lock chamber 2, a recovery robot 21 having the same construction as the loading robot 11 is provided. The recovery robot 21 holds, by use of an arm thereof, the substrate 9 in quantities of two simultaneously from the substrate holder 207 and places the substrates 9 on a substrate recovery stocker. Incidentally, the reason why the substrate charging stocker is provided is that if all substrates within a substrate charging chamber 12 are placed on the substrate charging stocker, it is possible to charge next substrates into substrate charging chamber 12, thereby making it possible to improve the productivity. This applies also to the substrate recovery stocker, and a substrate recovery chamber 22 is provided.

The vacuum chambers 4, 31 to 34, 50 to 54 and 500 arranged on the remaining three sides of the square are vacuum chambers that perform various kinds of treatments of the substrate 9. The vacuum chambers 31 to 34 at the corners of the square are direction changing chambers 31, 32, 33, 34 provided with direction changing means that changes the direction of the conveyed substrate holder 207 by 90 degrees. In this embodiment, the vacuum chamber 500 is a reserve chamber 500. This reserve chamber 500 is constructed as a chamber that cools the substrate 9 as required. After passing through this reserve chamber 500, the substrate 9 reaches the unload lock chamber 2 via the last direction changing chamber 34.

In FIG. 4, the substrate holder 207 holding the substrate 9 is conveyed clockwise within the thin-film forming apparatus 400. The treatment vacuum chamber into which the substrate 9 held by the substrate holder 207 is conveyed first is the preheat chamber 4 in which the substrate 9 is preliminarily heated to a prescribed temperature before film formation. After the preliminary heating in the preheat chamber 4, the substrate 9 is conveyed within one or a plurality of film formation chambers where a prescribed thin film is formed on the surface of the substrate 9. In this embodiment, the substrate 9 is conveyed within the plurality of film formation chambers 51, 52, 53, 54 and 50 arranged in series along the sides of the square. The film formation chambers 51, 52, 53, and 54 are sputtering film formation chambers in which film formation is performed on the substrate by sputtering, and the film formation chamber 50 is a protective film formation chamber. Incidentally, the vacuum chamber 200 capable being applied to the present invention can be adopted as at least one of the film forming treatment chambers, which are the preheat chamber 4, the film formation chambers 51 to 54 and the protective film formation chamber 50. For each of the film formation chambers 51 to 54, it is possible to select and adopt one vacuum treatment chamber from a physical vapor deposition (PVD) chamber, a chemical vapor deposition (CVD) chamber, a physical etching chamber, a chemical etching chamber, a substrate heating chamber, a substrate cooling chamber, an oxidizing treatment chamber, a reducing treatment chamber, and an ashing chamber, and the film formation chamber and at least one vacuum treatment chamber are connected without being exposed to the atmosphere.

A film-exfoliation preventing chamber 70 is provided between the load lock chamber 1 and the unload lock chamber 2. As with the chambers 51, 52, 53, 54, 50 in which a thin film is formed, also the film-exfoliation preventing chamber 70 is a vacuum chamber provided with an exhaust system (not shown).

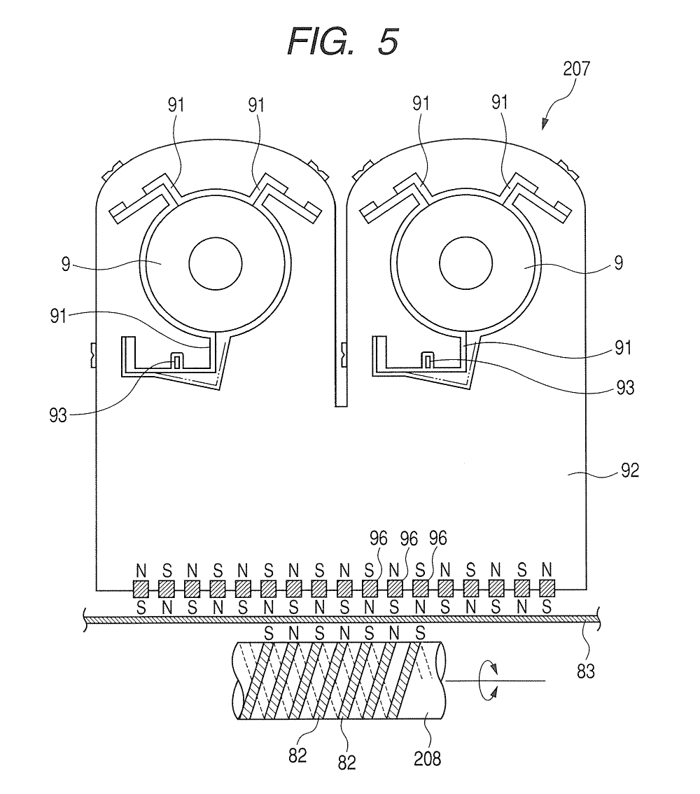

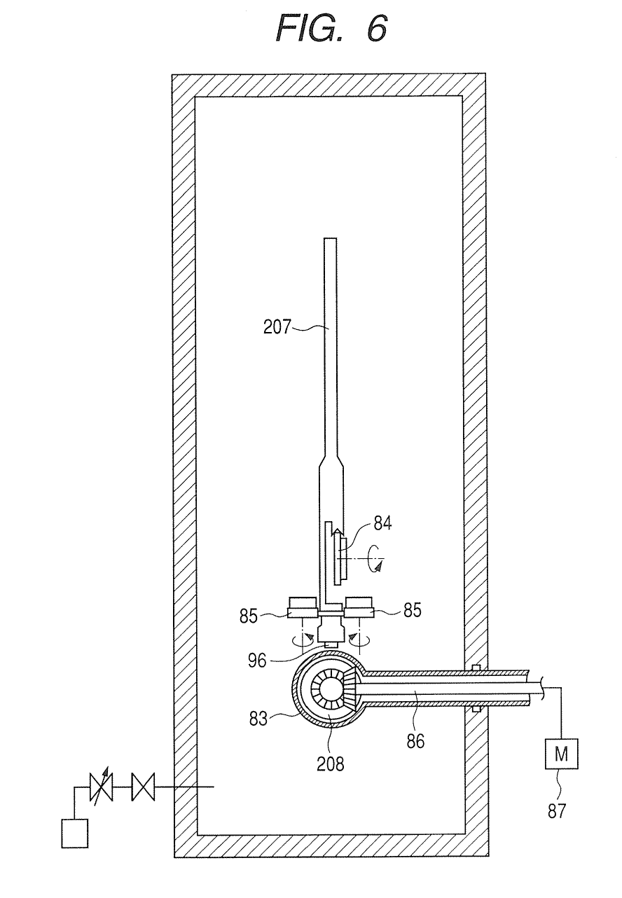

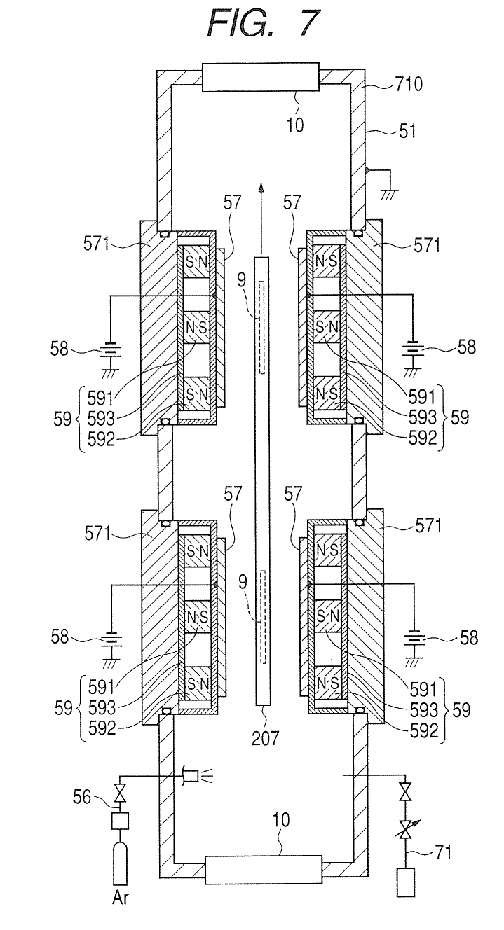

In the thin-film forming apparatus 400 of the first embodiment, the moving means ensures that the substrate 9 is sequentially treated by clockwise moving the substrate holder 207 holding the substrate 9 along a moving path 80. As an example of the moving means, linear moving means that linearly moves the substrate holder 207 will be described with reference to FIGS. 5 and 6.

FIGS. 5 and 6 are diagrams to illustrate the construction of the substrate holder 207 and moving means in the thin-film forming apparatus shown in FIG. 4, FIG. 5 being a schematic front view and FIG. 6 being a schematic side sectional view.

The substrate holder 207 is composed of a substrate-holder body 92 and holding claws 91 provided in a peripheral edge of the substrate-holder body 92. The holding claws 91 are provided in quantities of six in all and support the substrate 9 in sets of three. Out of such three holding claws 91, one holding claw 91 positioned on the lower side provides a movable holding claw. That is, a lever 93 that pushes down this holding claw 91 by opposing the elasticity thereof is provided. In loading the substrate 9 on the substrate holder 207, the holding claw 91 on the lower side is pushed down by use of the lever 93 and the substrate 9 is positioned within a circular opening of the substrate-holder body 92. And by returning the lever 93, the holding claw 91 on the lower side is returned to its original posture by using the elasticity thereof. As a result, the substrate 9 is locked by the three holding claws 91 and two substrates 9 are held by the substrate holder 207. The substrate 9 is recovered from the substrate holder 207 by completely reversing this operation. The substrate holder 207 is constructed so as to simultaneously hold two substrates 9. As shown in FIG. 5, the substrate holder 207 in this first embodiment is provided with a large number of magnets (hereinafter referred to as “holding-jig-side magnets”) 96 in a lower end part thereof. Each of the holding-jig-side magnets 96 has magnetic poles on the upper and lower surfaces thereof. As shown in FIG. 5, these holding-jig-side magnets 96 are arranged so as to have mutually reverse polarities along the arrangement direction.

On the lower side of the substrate holder 207, a conveyance magnet 208 is provided, with a partition wall 83 interposed therebetween. The conveyance magnet 208 is a member in the shape of a round bar, and has a spirally elongated magnet (hereinafter referred to as a “roller-side magnet”) 82 as shown in FIG. 5. This roller-side magnet 82 is provided in quantities of two with mutually different magnetic poles and provides a double spiral construction. The conveyance magnet 208 is arranged so that the roller-side magnet 82 faces the holding-jig-side magnets 96, with the partition wall 83 interposed therebetween. The partition wall 83 is formed from a material with a high magnetic permeability, and is magnetically coupled to the holding-jig-side magnets 96 and the roller-side magnet 82 through the partition wall 83. Incidentally, a space on the substrate holder 207 side of the partition wall 83 provides a vacuum (the interior side of each vacuum chamber) and a space on the conveyance magnet 208 side provides the atmosphere. This conveyance magnet 208 is provided along the square-shaped moving path 80 shown in FIG. 4.

As shown in FIG. 6, the substrate holder 207 is placed on a main pulley 84 that rotates around a horizontal rotation axis. The main pulley 84 is provided in large quantities along the moving direction of the substrate holder 207. A pair of sub pulleys 85, 85 that rotate around a vertical rotation axis abut against a lower end part of the substrate holder 207. The sub pulleys 85, 85 prevent the tilt of the substrate holder 207 by holding the lower end part of the substrate holder 207 so as to sandwich the substrate holder 207 from both ends. Also the sub pulleys 85, 85 are provided in large quantities along the moving direction of the substrate holder 207. As shown in FIG. 6, a driving rod 86 is connected to the conveyance magnet 208 via a bevel gear. And a motor 87 for movement is connected to the driving rod 86 so that the conveyance magnet 208 is rotated around the central axis thereof via the driving rod 86.

When the conveyance magnet 208 rotates, also the double spiral roller-side magnet 82 shown in FIG. 5 rotates. On this occasion, the condition of the rotation of the roller-side magnet 82 is similar to the condition which is such that as viewed from the holding-jig-side magnet 96, a plurality of magnets having alternately differing magnetic polarities align so as to form a line, and move linearly in the direction of the alignment. Therefore, the holding-jig-side magnets 96 that are magnetically coupled to the roller-side magnet 82 move linearly at the same time with the rotation of the roller-side magnet 82, with the result that the substrate holder 207 as a whole moves linearly. On this occasion, the main pulleys 85, 85 shown in FIG. 6 follow this movement.

FIG. 7 is a schematic side sectional view to illustrate the construction of the film-exfoliation preventing chamber 70 of the thin-film forming apparatus shown in FIG. 4. Like the above-described treatment chamber and the like, also the film-exfoliation preventing chamber 70 is an airtight vacuum chamber. The film-exfoliation preventing chamber 70 has an exhaust system 71. The exhaust system 71 can evacuate the interior of the film-exfoliation preventing chamber 70 to the order of 1×10⁻⁶ Pa. A gate valve 10 is provided on both ends of the film-exfoliation preventing chamber 70.

Film coating means is constructed so as to include a gas introduction system 56 that introduces a process gas to the interior, a target 57 provided so as to expose a surface to be sputtered exposed to an internal space, a sputtering power source 58 for applying voltage for a sputtering discharge to the target 57, and a magnet mechanism 59 provided behind the target 57. In this embodiment, tantalum (T) is used as the material for the target 57. In addition, examples of elements that may be used as the material for the target 57 include titanium (Ti), zirconium (Zr), hafnium (Hf), vanadium (V), niobium (Nb), chromium (Cr), molybdenum (Mo), tungsten (W), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al), gallium (Ga), indium (In), carbon (C), magnesium (Mg), silicon (Si) and manganese (Mn).

The exhaust system 71 can exhaust the interior of the film-exfoliation preventing chamber 70 to the order of 1×10⁻⁶ Pa. The gas introduction system 56 is constructed so as to be able to introduce a gas such as Argon as a process gas at a prescribed flow rate. The sputtering power source 58 is constructed so as to be able to apply a negative high voltage on the order of −300 V to −500 V to the target 57. The magnet mechanism 59 is intended for achieving a magnetron discharge, and is composed of a central magnet 591, a ring-like peripheral magnet 592 that surrounds this central magnet 591, and a plate-like yoke 593 that connects the central magnet 591 and the peripheral magnet 592. Incidentally, the target 57 and the magnet mechanism 59 are fixed to the film-exfoliation preventing chamber 70 via an insulating block 571. The film-exfoliation preventing chamber 70 is electrically grounded.

The interior of the film-exfoliation preventing chamber 70 is kept at a prescribed pressure by use of the exhaust system 71 while a process gas is being introduced by the gas introduction system 56, and in this condition, the sputtering power source 58 is brought into action. As a result of this, a sputtering discharge occurs and the target 57 is sputtered. Ta, which is the material for the sputtered target 57, reaches the substrate holder 207 and substrate holding claws 91, and coating films of Ta are formed on the surfaces of the substrate holder 207 and holding claws 91. Incidentally, as shown in FIG. 7, the set composed of the target 57, the magnet mechanism 59 and the sputtering power source 58 is provided on both sides, with the substrate holder 207 within the film-exfoliation preventing chamber 70 and the holding claws 91 interposed therebetween, and hence coating films are formed simultaneously on the substrate holder 207 and both sides of the holding claws 91. As shown in FIG. 7, the substrate holder 207 is arranged so as to be positioned at the front of the target 57 and coats the whole substrate holder 207.

The above-described embodiments do not limit the scope of the present invention and on the basis of the teachings and suggestions of the embodiments, the embodiments can be appropriately changed in order to realize the gist of the present invention in the scope thereof.

What is claimed is:

1. A sputtering apparatus comprising:
substrate holding means that holds a substrate; and
a gas introduction path in the shape of a closed curve that is arranged so as to surround the circumference of the substrate and has a plurality of gas spouts,
wherein the gas introduction path is provided so as to have substantially the same shape with respect to opposite surfaces of the substrate and has gas-introduction connections in at least two positions substantially opposed to each other on the closed curve.

2. The sputtering apparatus according to claim 1, wherein the plurality of gas spouts are provided symmetrically in the gas introduction path.

3. The sputtering apparatus according to claim 2, wherein the substrate holding means holds a plurality of substrates on the same plane and the gas introduction path is provided for each of the plurality of substrates.

4. The sputtering apparatus according to claim 2, wherein the gas introduction path is formed in the shape of a regular polygon or a circle.

5. The sputtering apparatus according to claim 1, wherein the number, size, shape and direction of the gas spouts can be adjusted.

6. The sputtering apparatus according to claim 2, wherein target placement beds are arranged, with the substrate holding means interposed therebetween.

7. A thin-film forming apparatus comprising:
a film forming treatment chamber provided with the sputtering apparatus according to claim 1; and
at least one vacuum treatment chamber that is a physical vapor deposition (PVD) chamber, a chemical vapor deposition (CVD) chamber, a physical etching chamber, a chemical etching chamber, a substrate heating chamber, a substrate cooling chamber, an oxidizing treatment chamber, a reducing treatment chamber, or an ashing chamber,
wherein the film forming treatment chamber and the at least one vacuum treatment chamber are connected without being exposed to the atmosphere.

8. A reactive sputtering method comprising:
supplying an inert gas to inside a vacuum chamber by use of the sputtering apparatus according to claim 1;
causing the inert gas to perform a plasma discharge;
sputtering a target; and
supplying a reactive gas to inside the vacuum chamber by use of the sputtering apparatus.
